(19) United States
(12) Patent Application Publication
(10) Pub. No.: US 2026/0262368 A1
(43) Pub. Date: Sep. 3, 2026

(54) DETECTION DEVICE

(71) Applicant: Japan Display Inc., Tokyo (JP)

(72) Inventor: Ken OHARA, Tokyo (JP)

(21) Appl. No.: 19/659,409

(22) Filed: Apr. 27, 2026

Related U.S. Application Data
(63) Continuation of application No. PCT/JP2024/038338, filed on Oct. 28, 2024.

(30) Foreign Application Priority Data
Nov. 14, 2023 (JP) 2023-193901

(51) Int. Cl. H10K 30/88; H10K 39/18; H10K 39/32; G06V 40/13; G06V 40/145

(52) U.S. Cl. CPC H10K 30/88; H10K 39/18; H10K 39/32; G06V 40/13; G06V 40/145

(57) ABSTRACT

According to an aspect, a detection device includes: a substrate having a plurality of divided areas; a plurality of photodiodes that are provided on the substrate, and in each of which a lower electrode, an active layer, and an upper electrode are stacked in the order as listed; and a plurality of sealing films that cover the photodiodes. Each of the divided areas includes at least one of the photodiodes and one of the sealing films. The one sealing film covers a side wall of the active layer.

### CROSS-REFERENCE TO RELATED APPLICATION

This application claims the benefit of priority from Japanese Patent Application No. 2023-193901 filed on November 14, 2023 and International Patent Application No. PCT/JP2024/038338 filed on October 28, 2024, the entire contents of which are incorporated herein by reference.

### BACKGROUND

### 1. Technical Field

What is disclosed herein relates to a detection device.

### 2. Description of the Related Art

Optical sensors capable of detecting fingerprint patterns and vein patterns are known (for example, Japanese Translation of PCT International Application Publication No. 2002-502120). Such optical sensors each include a plurality of photodiodes (organic photodiodes (OPDs)) each using an organic semiconductor material as an active layer. In each of the photodiodes, for example, a lower electrode, an electron transport layer, the active layer, a hole transport layer, and an upper electrode are stacked in this order.

A detection device that includes the OPDs is provided with a sealing film covering the OPDs. However, if pinholes or the like are formed in the sealing film, moisture may ingress into a detection area provided with the OPDs from outside the detection device. The active layer of the OPD may be reduced in detection sensitivity due to the moisture ingress.

For the foregoing reasons, there is a need for a detection device capable of reducing loss in the detection sensitivity of the photodiode.

### SUMMARY

According to an aspect, a detection device includes: a substrate having a plurality of divided areas; a plurality of photodiodes that are provided on the substrate, and in each of which a lower electrode, an active layer, and an upper electrode are stacked in the order as listed; and a plurality of sealing films that cover the photodiodes. Each of the divided areas includes at least one of the photodiodes and one of the sealing films. The one sealing film covers a side wall of the active layer.

### BRIEF DESCRIPTION OF THE DRAWINGS

FIG. 1 is a plan view schematically illustrating a detection device according to a first embodiment of the present disclosure;

FIG. 2 is a block diagram illustrating a configuration example of the detection device according to the first embodiment;

FIG. 3 is a circuit diagram illustrating the detection device according to the first embodiment;

FIG. 4 is a plan view schematically illustrating a plurality of photodiodes and a plurality of sealing films;

FIG. 5 is a sectional view taken along V-V' in FIG. 4;

FIG. 6 is a sectional view taken along VI-VI' in FIG. 4;

FIG. 7 is a plan view schematically illustrating a detection device according to a second embodiment of the present disclosure;

FIG. 8 is a sectional view taken along XIII-XIII' in FIG. 7; and

FIG. 9 is a sectional view taken along IX-IX' in FIG. 7.

### DETAILED DESCRIPTION

The following describes modes (embodiments) for carrying out the present disclosure in detail with reference to the drawings. The present disclosure is not limited to the description of the embodiments given below. Components described below include those easily conceivable by those skilled in the art or those substantially identical thereto. In addition, the components described below can be combined as appropriate. What is disclosed herein is merely an example, and the present disclosure naturally encompasses appropriate modifications easily conceivable by those skilled in the art while maintaining the gist of the present disclosure. To further clarify the description, the drawings may schematically illustrate, for example, widths, thicknesses, and shapes of various parts as compared with actual aspects thereof. However, they are merely examples, and interpretation of the present disclosure is not limited thereto. The same component as that described with reference to an already mentioned drawing is denoted by the same reference numeral through the present disclosure and the drawings, and detailed description thereof may not be repeated where appropriate.

In the present disclosure, in expressing an aspect of disposing another structure on or above a certain structure, a case of simply expressing "on" includes both a case of disposing the other structure immediately on the certain structure so as to contact the certain structure and a case of disposing the other structure above the certain structure with still another structure interposed therebetween, unless otherwise specified.

### First Embodiment

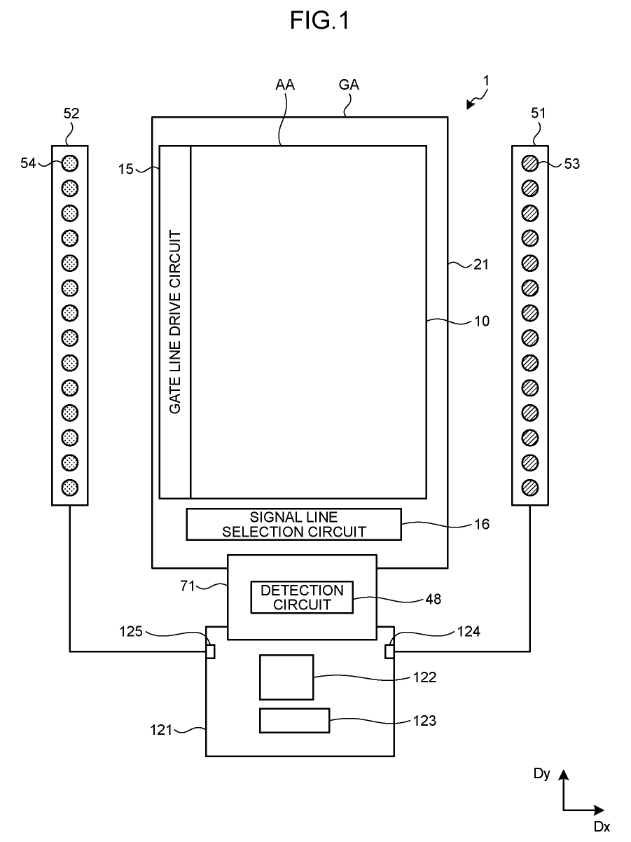

FIG. 1 is a plan view schematically illustrating a detection device according to a first embodiment of the present disclosure. As illustrated in FIG. 1, a detection device 1 includes a substrate 21, a sensor 10, a gate line drive circuit 15, a signal line selection circuit 16, a detection circuit 48, a control circuit 122, a power supply circuit 123, a first light source base member 51, a second light source base member 52, and light sources 53 and 54. The first light source base member 51 is provided with a plurality of the light sources 53. The second light source base member 52 is provided with a plurality of the light sources 54.

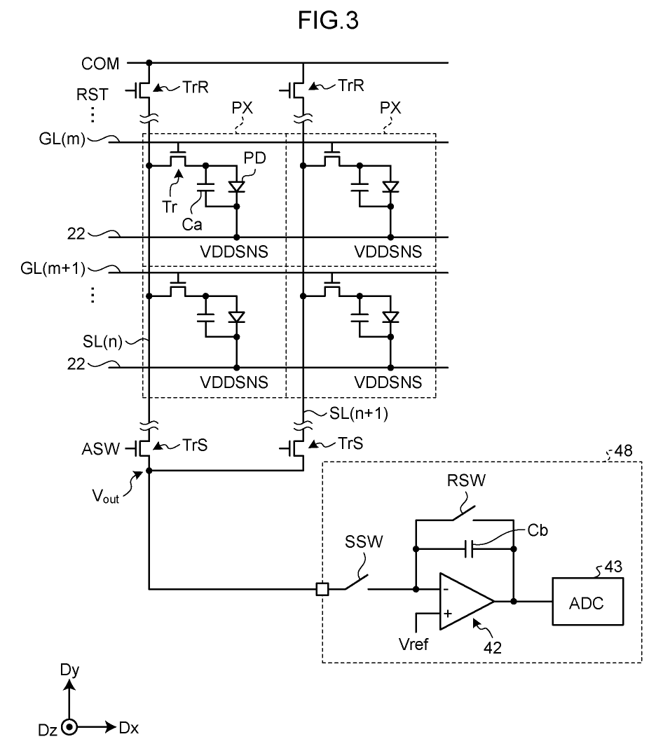

The substrate 21 is electrically coupled to a control substrate 121 through a wiring substrate 71. The wiring substrate 71 is, for example, a flexible printed circuit board or a rigid circuit board. The wiring substrate 71 is provided with the detection circuit 48. The control substrate 121 is provided with the control circuit 122 and the power supply circuit 123. The control circuit 122 is a field-programmable gate array (FPGA), for example. The control circuit 122 supplies control signals to the sensor 10, the gate line drive circuit 15, and the signal line selection circuit 16 to control detection operations of the sensor 10. The control circuit 122 also supplies control signals to the light sources 53 and 54 to control lighting and non-lighting of the light sources 53 and 54. The power supply circuit 123 supplies voltage signals, such as a sensor power supply signal (sensor power supply voltage) VDDSNS (refer to FIG. 3), to the sensor 10, the gate line drive circuit 15, and the signal line selection circuit 16. The power supply circuit 123 also supplies a power supply voltage to the light sources 53 and 54.

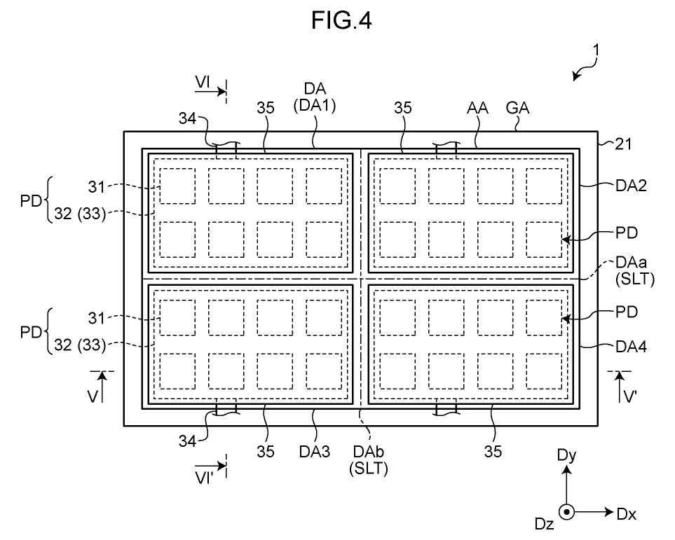

The substrate 21 has a detection area AA and a peripheral area GA. The detection area AA is an area provided with a plurality of photodiodes PD (refer to FIG. 4) included in the sensor 10. The peripheral area GA is an area between the outer perimeter of the detection area AA and the outer edges of the substrate 21, and is an area not provided with the photodiodes PD.

The gate line drive circuit 15 and the signal line selection circuit 16 are provided in the peripheral area GA. Specifically, the gate line drive circuit 15 is provided in an area extending along a second direction Dy in the peripheral area GA. The signal line selection circuit 16 is provided in an area extending along a first direction Dx in the peripheral area GA, and is provided between the sensor 10 and the detection circuit 48.

In the following description, the first direction Dx is one direction in a plane parallel to the substrate 21. A second direction Dy is one direction in the plane parallel to the substrate 21 and is a direction orthogonal to the first direction Dx. The second direction Dy may non-orthogonally intersect the first direction Dx. A third direction Dz is a direction orthogonal to the first direction Dx and the second direction Dy and is a direction normal to a principal surface of the substrate 21. The term "plan view" refers to a positional relation as viewed from a direction perpendicular to the substrate 21.

The light sources 53 are provided on the first light source base member 51, and arranged along the second direction Dy. The light sources 54 are provided on the second light source base member 52, and arranged along the second direction Dy. The first light source base member 51 and the second light source base member 52 are electrically coupled to the control circuit 122 and the power supply circuit 123, through respective terminals 124 and 125 provided on the control substrate 121.

For example, inorganic light-emitting diodes (LEDs) or organic electroluminescent (EL) diodes (organic light-emitting diodes (OLEDs)) are used as the light sources 53 and the light sources 54. The light sources 53 and 54 emit light having wavelengths different from each other.

First light emitted from the light sources 53 is mainly reflected on a surface of an object to be detected, such as a finger, and enters the sensor 10. As a result, the sensor 10 can detect a fingerprint by detecting a shape of asperities on the surface of the finger or the like. Second light emitted from the light sources 54 is reflected in the finger or the like, or transmitted through the finger or the like, and enters the sensor 10. As a result, the sensor 10 can detect information on a living body in the finger or the like. Examples of the information on the living body include, but are not limited to, pulse waves, pulsation, and a vascular image of the finger or a palm. That is, the detection device 1 may be configured as a fingerprint detection device to detect the fingerprint or a vein detection device to detect a vascular pattern of, for example, veins.

The arrangement of the light sources 53 and 54 illustrated in FIG. 1 is merely exemplary, and can be changed as appropriate. The detection device 1 is provided with a plurality of types of the light sources 53 and 54 as light sources. However, the light sources are not limited thereto, and may be of one type. For example, the light sources 53 and 54 may be arranged on each of the first and the second light source base members 51 and 52. The light sources 53 and 54 may be provided on one light source base member, or three or more light source base members. Alternatively, only at least one light source needs to be disposed.

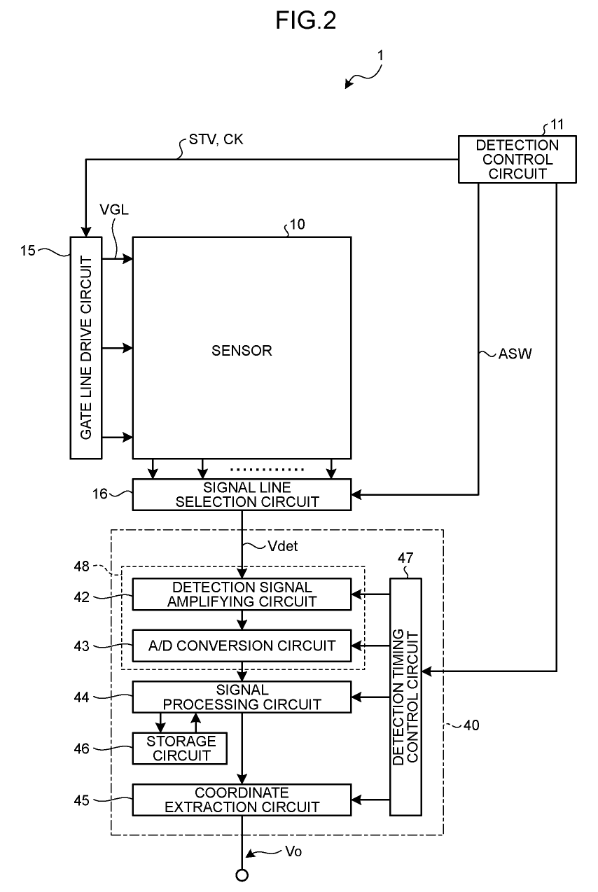

FIG. 2 is a block diagram illustrating a configuration example of the detection device according to the first embodiment. As illustrated in FIG. 2, the detection device 1 further includes a detection control circuit 11 and a detector (detection signal processing circuit) 40. The control circuit 122 includes one, some, or all functions of the detection control circuit 11. The control circuit 122 also includes one, some, or all functions of the detector 40 other than those of the detection circuit 48.

The sensor 10 includes the photodiodes PD. Each of the photodiodes PD included in the sensor 10 outputs an electrical signal corresponding to light emitted thereto as a detection signal Vdet to the signal line selection circuit 16. The sensor 10 performs the detection in response to a gate drive signal VGL supplied from the gate line drive circuit 15.

The detection control circuit 11 is a circuit that supplies respective control signals to the gate line drive circuit 15, the signal line selection circuit 16, and the detector 40 to control operations of these circuits. The detection control circuit 11 supplies various control signals including, for example, a start signal STV and a clock signal CK to the gate line drive circuit 15. The detection control circuit 11 also supplies various control signals including, for example, a selection signal ASW to the signal line selection circuit 16. The detection control circuit 11 also supplies various control signals to the light sources 53 and 54 to control lighting and non-lighting of each of the light sources 53 and 54.

The gate line drive circuit 15 is a circuit that drives a plurality of gate lines GL (refer to FIG. 3) based on various control signals. The gate line drive circuit 15 sequentially or simultaneously selects the gate lines GL, and supplies the gate drive signal VGL to the selected gate lines GL. Through this operation, the gate line drive circuit 15 selects the photodiodes PD coupled to the gate lines GL.

The signal line selection circuit 16 is a switch circuit that sequentially or simultaneously selects a plurality of signal lines SL (refer to FIG. 3). The signal line selection circuit 16 is a multiplexer, for example. The signal line selection circuit 16 couples the selected signal lines SL to the detection circuit 48 based on the selection signal ASW supplied from the detection control circuit 11. Through this operation, the signal line selection circuit 16 outputs the detection signals Vdet of the photodiodes PD to the detector 40.

The detector 40 includes the detection circuit 48, a signal processing circuit 44, a coordinate extraction circuit 45, a storage circuit 46, and a detection timing control circuit 47. The detection timing control circuit 47 controls the detection circuit 48, the signal processing circuit 44, and the coordinate extraction circuit 45 to operate these circuits synchronously based on a control signal supplied from the detection control circuit 11.

The detection circuit 48 is an analog front-end (AFE) circuit, for example. The detection circuit 48 is a signal processing circuit having functions of at least a detection signal amplifying circuit 42 and an analog-to-digital (A/D) conversion circuit 43. The detection signal amplifying circuit 42 amplifies the detection signals Vdet. The A/D conversion circuit 43 converts analog signals output from the detection signal amplifying circuit 42 into digital signals.

The signal processing circuit 44 is a logic circuit that detects predetermined physical quantities received by the sensor 10 based on output signals of the detection circuit 48. The signal processing circuit 44 can detect the asperities on the surface of the finger or the palm based on the signals from the detection circuit 48 when the finger is in contact with or in proximity to a detection surface. The signal processing circuit 44 can also detect the information on the living body based on the signals from the detection circuit 48. Examples of the information on the living body include, but are not limited to, the vascular image, the pulse waves, the pulsation, and a blood oxygen level of the finger or the palm.

The storage circuit 46 temporarily stores therein signals calculated by the signal processing circuit 44. The storage circuit 46 may be, for example, a random-access memory (RAM) or a register circuit.

The coordinate extraction circuit 45 is a logic circuit that obtains detected coordinates of the asperities on the surface of the finger or the like when the contact or proximity of the finger is detected by the signal processing circuit 44. The coordinate extraction circuit 45 is a logic circuit that obtains detected coordinates of blood vessels in the finger or the palm. The coordinate extraction circuit 45 combines the detection signals Vdet output from the respective photodiodes PD of the sensor 10 to generate two-dimensional information indicating the shape of the asperities on the surface of the finger or the like and two-dimensional information indicating the shape of the blood vessels in the finger or the palm. The coordinate extraction circuit 45 may output the detection signals Vdet as sensor output voltages Vo instead of calculating the detected coordinates.

FIG. 3 is a circuit diagram illustrating the detection device according to the first embodiment. FIG. 3 also illustrates a circuit configuration of the detection circuit 48. As illustrated in FIG. 3, a sensor pixel PX includes the photodiode PD, a capacitive element Ca, and a drive transistor Tr. The capacitive element Ca is capacitance (sensor capacitance) generated in the photodiode PD and is equivalently coupled in parallel to the photodiode PD.

FIG. 3 illustrates two gate lines GL(m) and GL(m+1) arranged in the second direction Dy among the gate lines GL. FIG. 3 also illustrates two signal lines SL(n) and SL(n+1) arranged in the first direction Dx among the signal lines SL. The sensor pixel PX is an area surrounded by the gate lines GL and the signal lines SL.

The drive transistors Tr are provided correspondingly to the photodiodes PD. Each of the drive transistors Tr is configured with a thin-film transistor, and in this example, configured with an n-channel metal-oxide-semiconductor (MOS) thin-film transistor (TFT).

Each of the gate lines GL is coupled to the gates of the drive transistors Tr arranged in the first direction Dx. Each of the signal lines SL is coupled to either the sources or the drains of the drive transistors Tr arranged in the second direction Dy. The others of the sources and the drains of the drive transistors Tr are each coupled to the anode of the photodiode PD and the capacitive element Ca.

The cathode of the photodiode PD is supplied with the sensor power supply signal VDDSNS from the power supply circuit 123 (refer to FIG. 1) via a power supply line 22. In FIG. 3, the power supply lines 22 extend in the first direction Dx, and each of the power supply lines 22 is coupled to the photodiodes PD, but is not limited to this configuration. The power supply lines 22 may be provided, for example, in the peripheral area GA and extend along each side of the substrate 21 so as to surround the photodiodes PD. The signal line SL and the capacitive element Ca are supplied with a sensor reference voltage COM serving as an initial potential of the signal line SL and the capacitive element Ca from the power supply circuit 123 via a reset transistor TrR.

When the sensor pixel PX is irradiated with light in an exposure period, a current corresponding to the intensity of the light flows through the photodiode PD. As a result, an electric charge is stored in the capacitive element Ca. When the drive transistor Tr is turned on in a readout period, a current corresponding to the electric charge stored in the capacitive element Ca flows through the signal line SL. The signal line SL is coupled to the detection circuit 48 via an output transistor TrS of the signal line selection circuit 16. Thus, the detection device 1 can detect a signal corresponding to the intensity of the light irradiating the photodiode PD for each of the sensor pixels PX.

In the readout period, a switch SSW is turned on to couple the detection circuit 48 to the signal line SL. The detection signal amplifying circuit 42 of the detection circuit 48 converts a current or an electric charge supplied from the signal line SL into a voltage corresponding thereto. A reference potential (Vref) having a fixed potential is supplied to a non-inverting input portion (+) of the detection signal amplifying circuit 42, and the signal line SL is coupled to an inverting input portion (-) of the detection signal amplifying circuit 42. In the present embodiment, the same signal as the sensor reference voltage COM is supplied as the reference potential (Vref) voltage. The control circuit 122 (refer to FIG. 1) calculates the difference between the detection signal Vdet when light irradiates the photodiode PD and the detection signal Vdet when light does not irradiate the photodiode PD as each of the sensor output voltages Vo. The detection signal amplifying circuit 42 includes a capacitive element Cb and a reset switch RSW. In a reset period, the reset switch RSW is turned on to reset the electric charge of the capacitive element Cb.

The drive transistor Tr is not limited to the n-type TFT and may be configured with a p-type TFT. The pixel circuit of the sensor pixel PX illustrated in FIG. 3 is merely exemplary. The sensor pixel PX may be provided with a plurality of transistors corresponding to one photodiode PD.

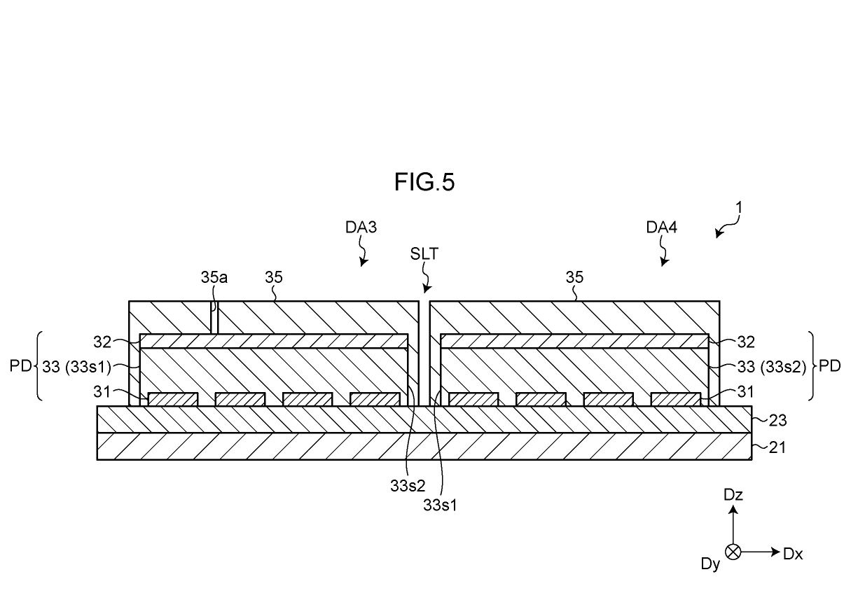

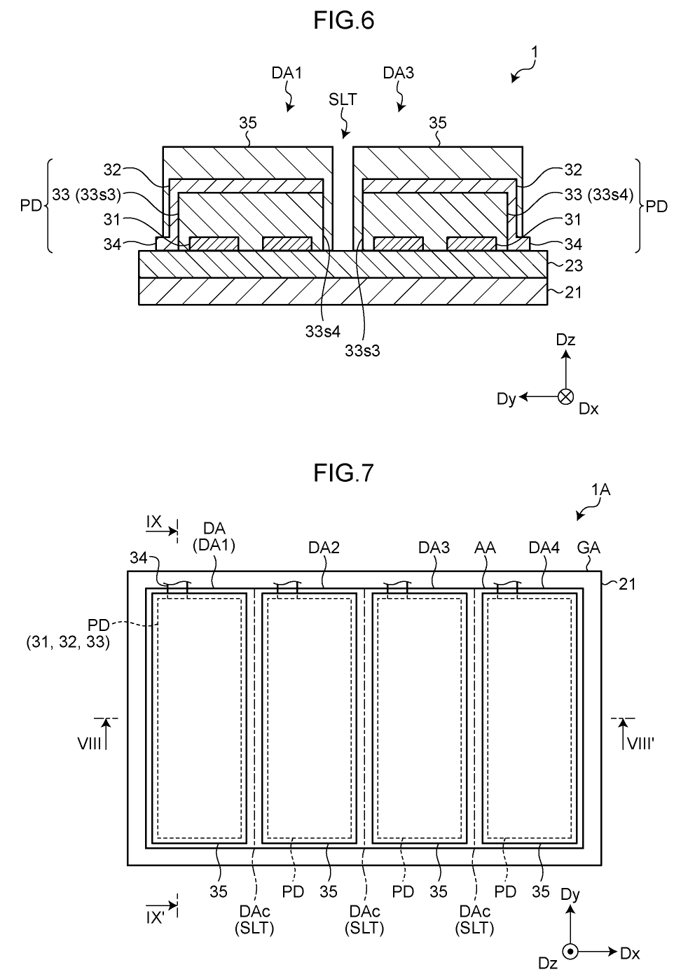

FIG. 4 is a plan view schematically illustrating the photodiodes and a plurality of sealing films. FIG. 5 is a sectional view taken along V-V' in FIG. 4. FIG. 6 is a sectional view taken along VI-VI' in FIG. 4. As illustrated in FIG. 4, the detection area AA of the substrate 21 includes a plurality of divided areas DA. In FIG. 4, boundaries DAa and DAb of the divided areas DA are schematically illustrated by long dashed short dashed lines. The divided areas DA are areas where the photodiodes PD are separately provided. A lower electrode 31, an active layer 33, and an upper electrode 32 (refer to FIGS. 5 and 6) that are included in the photodiode PD are not provided in an area overlapping the boundaries DAa and DAb of the divided areas DA.

The divided areas DA include four divided areas DA1, DA2, DA3, and DA4. The divided areas DA1, DA2, DA3, and DA4 are arranged in the first direction Dx and the second direction Dy, and are arranged in a matrix having a row-column configuration. The divided areas DA1 and DA2 are adjacent to each other in the first direction Dx. The divided areas DA3 and DA4 are adjacent to each other in the first direction Dx. The divided areas DA1 and DA3 are adjacent to each other in the second direction Dy. The divided areas DA2 and DA4 are adjacent to each other in the second direction Dy.

The length in the first direction Dx of each of the divided areas DA1, DA2, DA3, and DA4 is substantially equal to 1/2 the length in the first direction Dx of the detection area AA. The length in the second direction Dy of each of the divided areas DA1, DA2, DA3, and DA4 is substantially equal to 1/2 the length in the second direction Dy of the detection area AA.

In the following description, the divided areas DA1, DA2, DA3, and DA4 will each be simply referred to as a "divided area DA" when need not be distinguished from one another.

In the detection area AA, the photodiodes PD are arranged in the first direction Dx and the second direction Dy, thus being arranged in a matrix having a row-column configuration. Also, in each of the divided areas DA, the photodiodes PD are arranged in the first direction Dx and the second direction Dy, thus being arranged in a matrix having a row-column configuration. For example, the photodiodes PD are arranged in two rows and four columns in each of the divided areas DA.

As illustrated in FIGS. 5 and 6, a circuit forming layer 23 and the photodiodes PD are stacked in this order on the substrate 21. The circuit forming layer 23 is a layer that is provided on the substrate 21, and in which various transistors, such as the drive transistors Tr, and various types of wiring, such as the gate lines GL and the signal lines SL, illustrated in FIG. 3 are formed.

The photodiodes PD are provided on the circuit forming layer 23. Each of the photodiodes PD includes the lower electrode 31, the active layer 33, and the upper electrode 32. The lower electrode 31, the active layer 33, and the upper electrode 32 are stacked in this order on the substrate 21. The photodiode PD of the present embodiment is an organic photodiode (OPD) that uses an organic semiconductor as the active layer 33.

The lower electrode 31 is an anode electrode of the photodiode PD and is formed, for example, of a light-transmitting conductive material such as indium tin oxide (ITO).

The active layer 33 changes in characteristics (for example, voltage-current characteristics and resistance value) depending on light emitted thereto. An organic material is used as a material of the active layer 33. Specifically, the active layer 33 has a bulk heterostructure containing a mixture of a p-type organic semiconductor and an n-type fullerene derivative ((6,6)-phenyl-C₆₁-butyric acid methyl ester (PCBM)) that is an n-type organic semiconductor. As the active layer 33, low-molecular-weight organic materials can be used including, for example, fullerene (C₆₀), phenyl-C₆₁-butyric acid methyl ester (PCBM), copper phthalocyanine (CuPc), fluorinated copper phthalocyanine (F₁₆CuPc), 5,6,11,12-tetraphenyltetracene (rubrene), and perylene diimide (PDI) (derivative of perylene).

The active layer 33 can be formed by a vapor deposition process (dry process) using any of the low-molecular-weight organic materials listed above. In this case, the active layer 33 may be, for example, a multilayered film of CuPc and F₁₆CuPc, or a multilayered film of rubrene and C₆₀. The active layer 33 can also be formed by a coating process (wet process). In this case, the active layer 33 is made using a material obtained by combining any of the above-listed low-molecular-weight organic materials with a high-molecular-weight organic material. As the high-molecular-weight organic material, for example, poly(3-hexylthiophene) (P3HT) and F8-alt-benzothiadiazole (F8BT) can be used. The active layer 33 can be a film made of a mixture of P3HT and PCBM, or a film made of a mixture of F8BT and PDI.

The upper electrode 32 is provided on the active layer 33. The upper electrode 32 is a cathode electrode of the photodiode PD and is formed, for example, of a light-transmitting conductive material such as ITO or indium zinc oxide (IZO). The upper electrode 32 may be a multilayered film of a plurality of light-transmitting conductive materials.

The photodiode PD may have buffer layers (electron transport layer, hole transport layer, and other layers) between the lower electrode 31 and the active layer 33, and between the upper electrode 32 and the active layer 33. The buffer layers are provided to facilitate holes and electrons generated in the active layer 33 to reach the lower electrode 31 or the upper electrode 32.

As illustrated in FIGS. 4 to 6, the lower electrodes 31 are provided, one for each of the photodiodes PD, such that the lower electrodes 31 are separated from each other between adjacent photodiodes PD. The active layer 33 and the upper electrode 32 are provided continuously across the photodiodes PD (lower electrodes 31). The active layer 33 and the upper electrode 32 cover the lower electrodes 31 of the photodiodes PD. The active layers 33 are provided, one for each of the divided areas DA, such that the active layers 33 are separated from each other between adjacent divided areas DA. The upper electrodes 32 are provided, one for each of the divided areas DA, such that the upper electrodes 32 are separated from each other between adjacent divided areas DA.

The detection device 1 includes a plurality of sealing films 35 that cover the photodiodes PD. The sealing films 35 are arranged, one for each of the divided areas DA, such that the sealing films 35 are separated from each other between adjacent divided areas DA. As illustrated in FIG. 4, the sealing films 35 are arranged in the first direction Dx and the second direction Dy, thus being arranged in a matrix having a row-column configuration. An inorganic film, such as a silicon nitride film or an aluminum oxide film, or a resin film, such as an acrylic film, is used as each of the sealing films 35. The sealing film 35 is not limited to a single layer, but may be a multilayered film of two or more layers combining the inorganic insulating film with the organic insulating film (resin film) mentioned above.

The adjacent sealing films 35 are separated by slits SLT extending in the first direction Dx and the second direction Dy. In more detail, the sealing film 35 of the divided area DA1 and the sealing film 35 of the divided area DA3 that are adjacent in the second direction Dy are separated from each other, and the sealing film 35 of the divided area DA2 and the sealing film 35 of the divided area DA4 that are adjacent in the second direction Dy are separated from each other, by a slit SLT (first slit) that extends in the first direction Dx. The sealing film 35 of the divided area DA1 and the sealing film 35 of the divided area DA2 that are adjacent in the first direction Dx are separated from each other, and the sealing film 35 of the divided area DA3 and the sealing film 35 of the divided area DA4 that are adjacent in the first direction Dx are separated from each other, by a slit SLT (second slit) that extends in the second direction Dy.

As illustrated in FIGS. 4 to 6, each of the divided areas DA includes more than one of the photodiodes PD (eight photodiodes PD) and one sealing film 35. In each of the divided areas DA, one sealing film 35 is provided so as to cover top surfaces and side walls of photodiodes PD.

In more detail, as illustrated in FIGS. 5 and 6, the active layer 33 of the photodiode PD includes a side wall 33s1 that faces one side in the first direction Dx (left side in FIG. 5), a side wall 33s2 that is opposite to the side wall 33s1 and faces the other side in the first direction Dx (right side in FIG. 5), a side wall 33s3 that faces one side in the second direction Dy (left side in FIG. 6), and a side wall 33s4 that is opposite to the side wall 33s3 and faces the other side in the second direction Dy (right side in FIG. 6).

In each of the divided areas DA, one sealing film 35 covers the upper electrode 32 of the photodiodes PD and all of the side walls 33s1, 33s2, 33s3, and 33s4 of the active layer 33.

Thus, since the sealing film 35 is provided so as to cover the photodiodes PD, moisture ingress from the outside can be inhibited. The active layers 33 of the photodiodes PD are provided, one for each of the divided areas DA, such that the active layers 33 are separated from each other between adjacent divided areas DA. In each of the divided areas DA, the sealing film 35 is provided so as to cover the photodiodes PD. With this configuration, as illustrated in FIG. 5, even if a pinhole 35a is formed in the sealing film 35 in one of the divided areas DA (for example, divided area DA3) and moisture ingresses into the photodiodes PD in the divided area DA3, the moisture ingress into the photodiodes PD in the other divided areas DA1, DA2, and DA4 is inhibited. As a result, even if the detection sensitivity of the photodiodes PD in the divided area DA3 is reduced due to the moisture ingress, the decrease in the detection sensitivity of the photodiodes PD in at least the other divided areas DA1, DA2, and DA4 due to the moisture ingress can be reduced. Therefore, the detection device 1 can reduce the loss in the detection sensitivity of the photodiodes PD as compared with a configuration in which the active layer 33 is provided over the entire detection area AA and one sealing film 35 is provided over the multiple photodiodes PD.

As illustrated in FIGS. 4 and 6, a lead-out line 34 is coupled to the upper electrode 32. The lead-out line 34 is provided correspondingly to the outermost photodiode PD in the second direction Dy. The lead-out line 34 is provided at the upper electrode 32 of each of the divided areas DA, and extends in the second direction Dy. The lead-out line 34 is provided along the side wall 33s3 or the side wall 33s4 in the second direction Dy of the active layer 33, and is led out of the sealing film 35 through a gap between the lower end of the sealing film 35 and the circuit forming layer 23. The lead-out line 34 is coupled to the power supply line 22 (refer to FIG. 3), and supplied with the sensor power supply signal VDDSNS (power supply) through the power supply line 22.

With this configuration, the sensor power supply signal VDDSNS (power supply) can be well supplied to the multiple photodiodes PD via the lead-out line 34 even in the configuration in which the upper electrodes 32 are provided one for each of the divided areas DA such that the upper electrode 32 are separated from each other between adjacent divided areas DA, and the sealing film 35 is provided over the multiple photodiodes PD in each of the divided areas DA. The position, width, number of lines, and other parameters of the lead-out line 34 are only exemplary and can be changed as appropriate.

The configuration of the photodiodes PD and the sealing films 35 illustrated in FIGS. 4 to 6 is merely exemplary, and can be changed as appropriate. For example, the photodiodes PD are arranged in two rows and four columns in each of the divided areas DA, but the arrangement is not limited thereto. At least one photodiode PD needs to be provided in the divided area DA. Alternatively, the photodiodes PD may be arranged in three or more rows, three or fewer columns, or five or more columns in the divided area DA.

### Second Embodiment

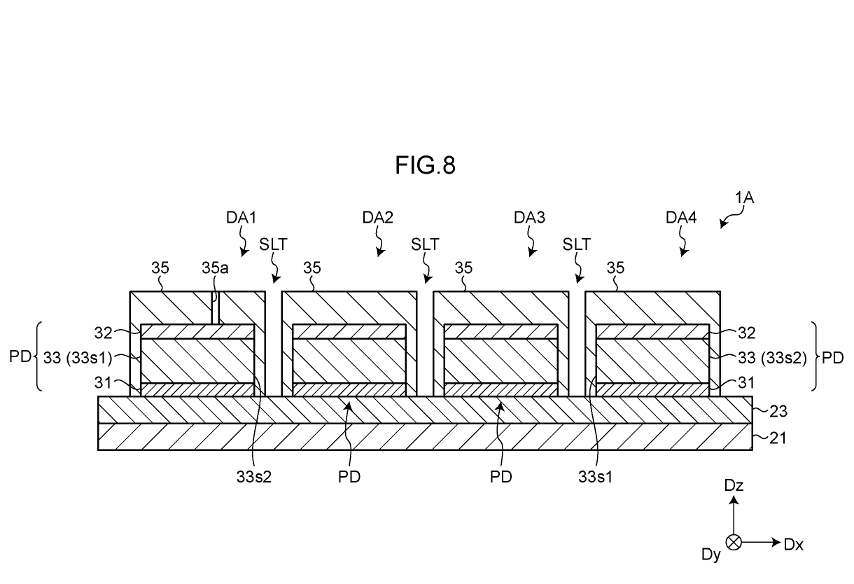

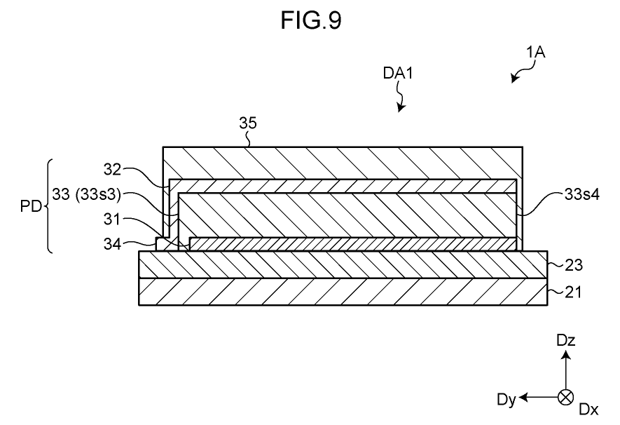

FIG. 7 is a plan view schematically illustrating the detection device according to the second embodiment. FIG. 8 is a sectional view taken along XIII-XIII' in FIG. 7. FIG. 9 is a sectional view taken along IX-IX' in FIG. 7. In the following description, the same components as those described in the embodiment described above are denoted by the same reference numerals, and the description thereof will not be repeated.

As illustrated in FIGS. 7 to 9, in a detection device 1A according to the second embodiment, the divided areas DA1, DA2, DA3, and DA4 are arranged in the first direction Dx. The length in the first direction Dx of each of the divided areas DA1, DA2, DA3, and DA4 is substantially equal to 1/4 the length in the first direction Dx of the detection area AA. The length in the second direction Dy of each of the divided areas DA1, DA2, DA3, and DA4 is substantially equal to the length in the second direction Dy of the detection area AA.

The photodiodes PD are provided, one for each of the divided areas DA. That is, one photodiode PD is provided in one divided area DA. As illustrated in FIGS. 8 and 9, in each of the divided areas DA, the lower electrode 31, the active layer 33, and the upper electrode 32 are stacked in this order in the photodiode PD. In the present embodiment, the active layer 33 and the upper electrode 32 are provided so as to cover one lower electrode 31.

The sealing films 35 are provided, one for each of the divided areas DA, and arranged in the first direction Dx. The sealing films 35 adjacent in the first direction Dx are separated by the slit SLT that extends in the second direction Dy.

In other words, each of the divided areas DA includes one photodiode PD and one sealing film 35. The one sealing film 35 covers the upper electrode 32, and the side walls 33s1, 33s2, 33s3, and 33s4 of the active layer 33 of the one photodiode PD.

With this configuration, in the same way as in the first embodiment, even if the pinhole 35a is formed in the sealing film 35 in one of the divided areas DA (for example, divided area DA1) and the detection sensitivity of the photodiode PD in the divided area DA1 decreases due to the moisture ingress, the decrease in the detection sensitivity of the photodiodes PD in the other divided areas DA2, DA3, and DA4 due to the moisture ingress can be reduced.

As illustrated in FIGS. 7 and 9, the lead-out line 34 is provided along the side wall 33s3 of the active layer 33 of the photodiode PD extending in the second direction Dy, and is led out of the sealing film 35. The lead-out line 34 is coupled to the power supply line 22 (refer to FIG. 3), and supplied with the sensor power supply signal VDDSNS (power supply).

In the second embodiment, four photodiodes PD are arranged in the first direction Dx, but the number of the photodiodes PD is not limited to four. In the detection device 1A, three or five or more photodiodes PD may be arranged in the first direction Dx.

While the preferred embodiments of the present disclosure have been described above, the present disclosure is not limited to the embodiments described above. The content disclosed in the embodiments is merely an example, and can be variously modified within the scope not departing from the gist of the present disclosure. Any modifications appropriately made within the scope not departing from the gist of the present disclosure also naturally belong to the technical scope of the present disclosure. At least one of various omissions, substitutions, and changes of the components can be made without departing from the gist of the embodiments and the modifications thereof described above.

What is claimed is:

1. A detection device comprising:
a substrate having a plurality of divided areas;
a plurality of photodiodes that are provided on the substrate, and in each of which a lower electrode, an active layer, and an upper electrode are stacked in the order as listed; and
a plurality of sealing films that cover the photodiodes, wherein
each of the divided areas comprises at least one of the photodiodes and one of the sealing films, and
the one sealing film covers a side wall of the active layer.

2. The detection device according to claim 1, wherein
the sealing films are arranged in a first direction, and
the sealing films adjacent in the first direction are separated by a slit that extends in a second direction intersecting the first direction.

3. The detection device according to claim 1, wherein
the sealing films are arranged in a matrix having a row-column configuration in a first direction and a second direction intersecting the first direction,
the sealing films adjacent in the second direction are separated from each other by a first slit that extends in the first direction, and
the sealing films adjacent in the first direction are separated from each other by a second slit that extends in the second direction.

4. The detection device according to claim 1, wherein
each of the divided areas comprises more than one of the photodiodes, and
the lower electrodes are provided, one for each of the photodiodes, such that the lower electrodes are separated from each other between adjacent photodiodes,
the active layer and the upper electrode cover the lower electrodes,
the active layers are provided, one for each of the divided areas, such that the active layers are separated from each other between adjacent divided areas, and
the upper electrode are provided, one for each of the divided areas, such that the upper electrode are separated from each other between adjacent divided areas.

5. The detection device according to claim 1, comprising lead-out line coupled to the upper electrode, wherein
the lead-out line is provided along a portion of the side wall of the active layer of the photodiode and led out of the sealing film.

6. The detection device according to claim 5, wherein
the sealing films are arranged in a matrix having a row-column configuration in a first direction and a second direction intersecting the first direction, and
the lead-out line is provided correspondingly to an outermost one of the photodiodes in the second direction, provided along the side wall of the active layer in the second direction, and is configured to be supplied with power from outside the sealing film.

7. The detection device according to claim 5, wherein
the sealing films are arranged in a first direction, and
the lead-out line is provided along the side wall of the active layer of the photodiode extending in a second direction intersecting the first direction, and is configured to be supplied with power from outside the sealing film.

8. The detection device according to claim 1, wherein the photodiode is an organic photodiode (OPD).
